(19) United States
(12) Patent Application Publication
(10) Pub. No.: US 2004/0165341 A1
(43) Pub. Date: Aug. 26, 2004

(54) Electronic units and connections

(75) Inventor: Peter Dent, London (GB)

Correspondence Address: CONNOLLY BOVE LODGE & HUTZ LLP, SUITE 800, 1990 M STREET NW, WASHINGTON, DC, 20036-3425, US

(73) Assignee: Smiths Group plc, London (GB)

(21) Appl. No.: 10/752,688

(22) Filed: Jan. 8, 2004

(30) Foreign Application Priority Data
Jan. 11, 2003 (GB) 0300616.0

(51) Int. Cl. H05K 5/00

(52) U.S. Cl. 361/679

(57) ABSTRACT

An avionics housing has electrical connectors mounted centrally on a front face. Transient voltage suppressors are located in an array of holes in a metal plate to each side of the connectors, beneath removable panels so that they are accessible on the front face after removal of the panels. The suppressors extend through the plate to connect with circuit boards on the opposite side that have tracks connecting with the connectors. A filter module is secured behind the circuit boards and supports filters that connect with connections on the boards. A rear connection assembly carries connectors on its rear surface by which connection is made to circuits within the unit. Flexi-rigid circuits interconnect the rear connectors with socket array boards on the front of the rear connection assembly and these, in turn, connect with contacts on the filter module.

### BACKGROUND OF THE INVENTION

This invention relates to electronic units and connections.

The invention is more particularly concerned with units, such as avionics ARINC units, containing electronic circuits and components within a housing on which is mounted an electrical connector by which electrical connection is made to and from the unit.

In order to protect the circuits and components within the unit from transient voltages such as caused by lightning strikes or the like, it is common practice for the connector to have associated with it suppression devices such as diodes that conduct the transient voltage to ground. Connectors may have several hundred contacts each of which have to be individually connected to ground via a TVS (transient voltage suppressor). Where the TVSs are mounted within the unit itself replacement is a problem because the unit has to be opened and retested in an approved manner after sealing closed. Alternatively, the TVS devices can be mounted directly on the contacts, which are constructed so that they can be removed individually from the front of the connector. The problem with this approach is that the TVS devices must be of a special construction in order to be mounted on the contacts, which may make them more expensive and less reliable than conventional devices.

### BRIEF SUMMARY OF THE INVENTION

It is an object of the present invention to provide an alternative electronics unit.

According to the present invention there is provided an electronics unit including an outer housing, electronics components within the housing and an electrical connector on a face of the outer housing making electrical connection with the components within the housing, a plurality of electrical devices being connected between the connector and the housing, and the devices being located on the face to one side of the connector and being accessible without removal of the connector.

The devices may be transient voltage suppressors and may each include a diode. The devices are preferably located in individual holes in a metal plate and may be located beneath a removable panel on the face. The panel is preferably sealed with the face by a gasket. Each device may include a clip by which electrical connection is made to the device. The devices and the contacts of the connector are preferably mounted on a support plate to be accessible on a front surface of the plate, the devices and contacts each extending through the plate and having contacts exposed on a rear surface of the support plate. The unit may include one or more circuit boards having contacts located on a forward surface arranged to make electrical contact with respective ones of the contacts exposed on the rear surface of the support plate. The circuit boards are preferably arranged electrically to interconnect the devices with the contacts of the connectors. The unit may include a filter module including a plate supporting an array of filters arranged in the same configuration as the contacts of the connector. The filters each may have a contact on the front surface of the filter plate and a contact on the rear surface of the filter plate. The unit preferably includes a rear connector assembly including a support plate having one or more connectors mounted on a rear surface, one or more socket array boards mounted on a forward surface of the plate and one or more flexi-rigid circuits extending around one or more edges of the plate to interconnect the connectors on the rear surface with the socket array boards on the forward surface. The socket array boards are preferably arranged to make electrical connection with respective ones of the filters.

An avionics unit according to the present invention will now be described, by way of example, with reference to the accompanying drawings.

### BRIEF DESCRIPTION OF THE DRAWINGS

FIG. 1 is a perspective view of the unit from the front with its casing moved rearwardly by a small distance;

FIG. 2 is a perspective view of the front of the unit with a panel removed from the front face;

FIG. 3 is an exploded perspective view of the rear side of a part of the front of the unit;

FIG. 4 is an exploded perspective view from the front showing the rear connector assembly separated rearwardly; and

FIG. 5 is an exploded perspective view of the front of the unit from the rear showing the rear connector assembly separated rearwardly.

### DETAILED DESCRIPTION OF THE PREFERRED EMBODIMENT

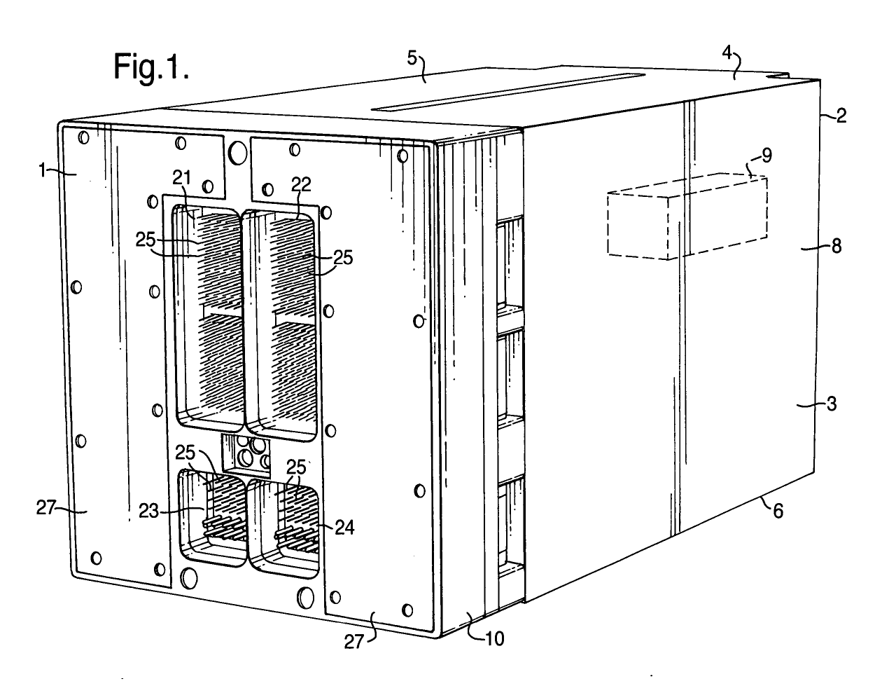

With reference first to FIG. 1, the avionics unit is of a conventional size and shape with square front and rear faces 1 and 2, and rectangular side faces 3 to 6. The housing of the unit includes a sheet metal casing 8 slid rearwardly a short distance in FIG. 1 to show the front sub-assembly 10 of the unit. The avionics unit contains conventional electronic circuits and components indicated generally by the numeral 9.

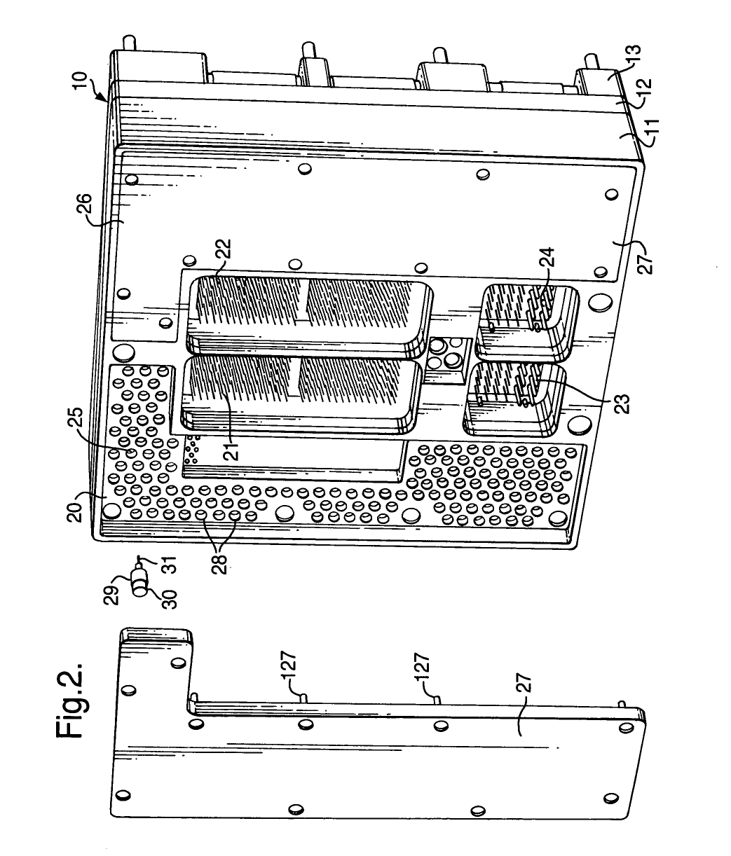

With reference now also to FIGS. 2 to 5, the sub-assembly 10 comprises a front connector assembly 11, a filter module 12 located behind the front assembly and a rear connector assembly 13 located behind the filter module.

The front connector assembly 11 includes an aluminium support plate 20 supporting two rectangular electrical connectors 21 and 22 and two square connectors 23 and 24 recessed within the front face 1 and each having multiple contacts 25 accessible from the front face. The rectangular connectors 21 and 22 are located side-by-side above the square connectors 23 and 24. The connectors 21 to 24 are located midway across the width of the front face 1 and are bordered on opposite sides by respective L-shape recesses 25 and 26. The recesses 25 and 26 are covered by two cover plates 27 secured to the support plate 20 by screws 127. Gaskets (not shown) provide a seal between the cover plates 27 and the support plate 20. The recesses 25 and 26 have an array of holes 28 machined through the thickness of the support plate 20, one for each of the contacts 25 on the connectors 21 to 24. Each hole 28 mounts a respective TVS in the form of a diode 29 (FIG. 2). The diodes 29 are of the form sold by Sabritec, Inc of Irvine, Calif. and are of cylindrical shape with one electrode provided by a circumferential spring clip 30 and a second electrode provided by an axially extending pin 31. The diodes 29 are fitted within the holes 28 with their axial electrodes 31 extending rearwardly and with their spring clips 30 retaining the diodes in the support plate 20 and making electrical connection with the support plate and, via this, with ground.

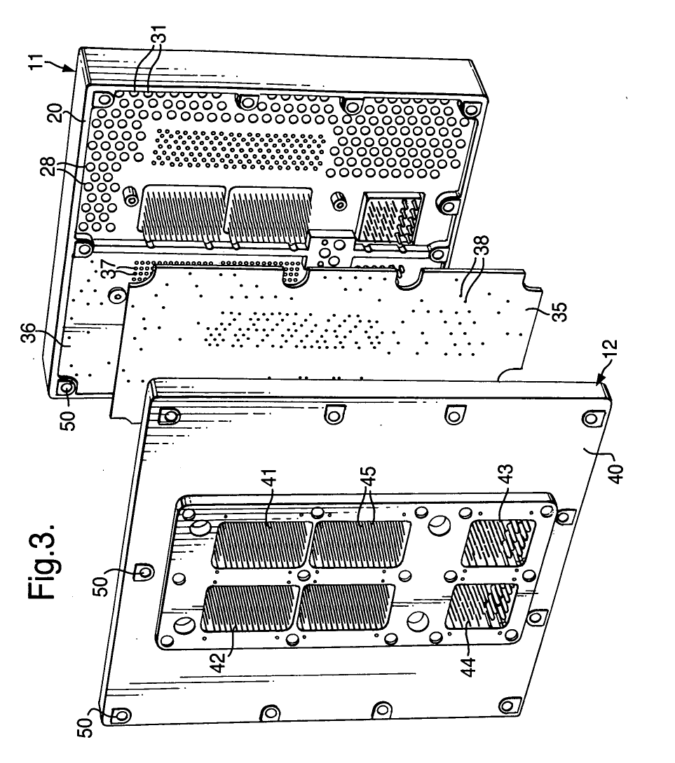

FIG. 3 shows the pins 31 of the diodes 29 projecting from the rear side of the support plate 20, these pins being electrically isolated from the holes 28 in the plate. Electrical connection between the contacts 25 of the connectors 21 to 24 and respective ones of the pins 31 of the diodes 29 is made by two circuit boards 35 and 36, which overlay the connectors 21 and 23 and the connectors 22 and 24 respectively. The circuit boards 35 and 36 have a first array of holes 37 containing low profile contacts which make plug-in connection with the contacts 25. Similarly, a second array of holes 38 on the boards 35 and 36 contains low profile contacts which make connection with the diode pin electrodes 31. Conductive tracks (not shown) in the boards 35 and 36 interconnect respective ones of the connector contacts 25 with respective ones of the diodes 29 so that high voltage transients on any one of the contacts are conducted via a respective diode to ground.

The filter module 12 is secured to the rear of the front connector assembly 11 over the boards 35 and 36. The filter module 12 comprises an aluminium plate 40 supporting four connectors 41 to 44 corresponding to the connectors 21 to 24 on the front face 1 of the sub-assembly 10. The contact pins 45 of the connectors 41 to 44 include filters (not shown) of a conventional kind. In particular, the filter module 12 has a filter for each contact pin 45, the pins extending through apertures in two parallel capacitor array boards each of which is connected to ground. The filters are arranged in an array corresponding to the configuration of the contacts 25 of the connectors 21 to 24. Each pin 45 carries a ferrite bead acting as an inductor, between the capacitor array boards. Signals on the filter pins 45 within selected frequency ranges are conducted via the capacitor array boards to the plate 40 and to ground.

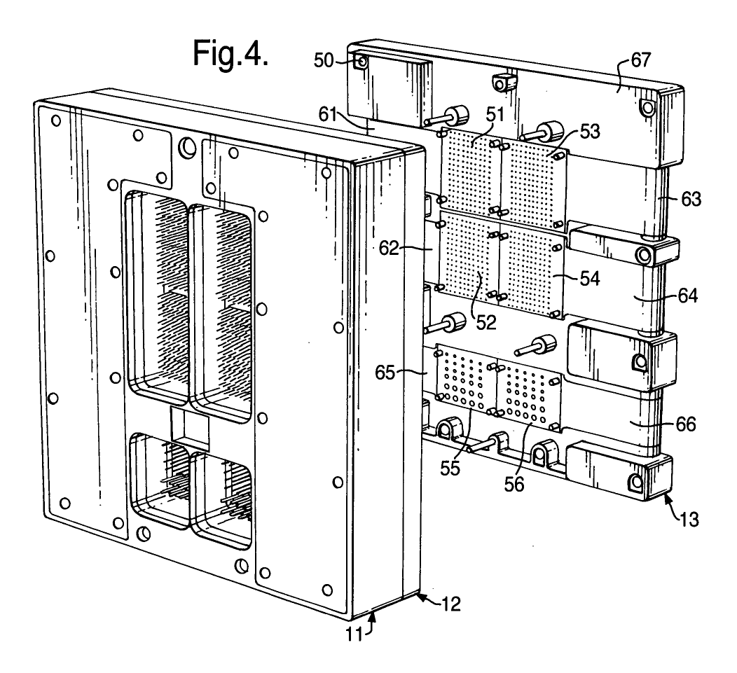

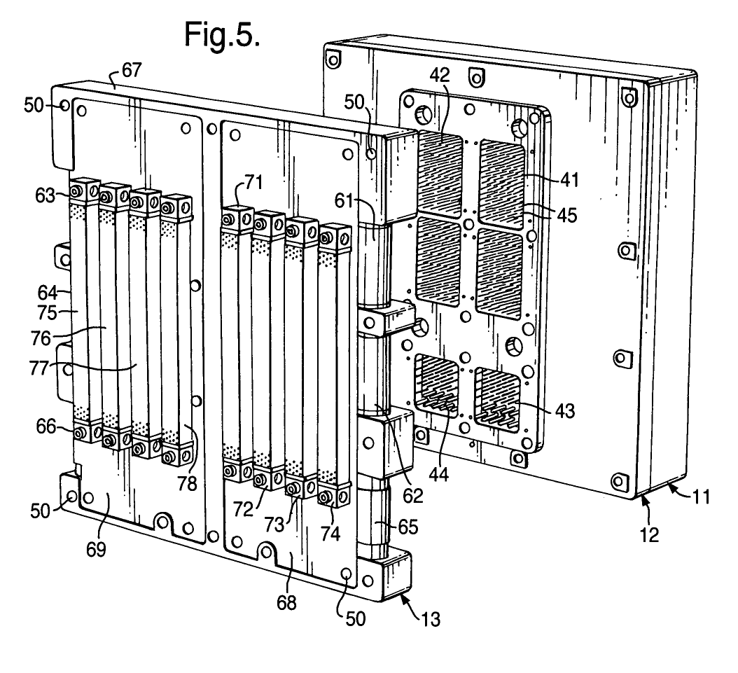

The sub-assembly 10 is completed by the rear connector assembly 13 (most clearly shown in FIGS. 4 and 5) secured with the filter module 12 and front connector assembly 11 by bolts (not shown) passing through holes 50 around the edge of the assemblies. The rear connector assembly 13 is electrically connected with the filter module 12 by plug-in connection of the contact pins 45 on the connectors 41 to 44. This is achieved by means of six, square socket array boards 51 to 56 carrying a socket 57 for making plug-in connection with respective contacts 45 on the connectors 41 to 44. Two of the boards 51 and 52 are aligned with upper and lower halves of the rectangular connector 41, another two boards 53 and 54 are aligned with the upper and lower halves of the other rectangular connector 42, and the remaining two boards 55 and 56 are aligned with the two square connectors 43 and 44 respectively. The socket boards 51 to 56 are mounted at one end of respective flexi-rigid circuit strips 61 to 66 extending laterally outwardly and wrapped around the edges of an aluminium support plate 67. The other end of the circuit strips 61, 62 and 65 are connected to a rectangular circuit board 68 attached to the rear surface of the support plate 67. Similarly, the circuit strips 63, 64 and 66 are connected to a rectangular circuit board 69. The circuit boards 68 and 69 each support four rectangular connectors 71 to 74 and 75 to 78 by which connection is made to the various circuits 9 within the avionics unit.

The arrangement of the present invention enables diodes to be removed and replaced from the front of the avionics unit without the need to open the avionics unit itself. The diodes used can be of a conventional kind that are readily available in a reliable form. Instead of diodes, the invention could be used to mount other electrical devices, such as, for example, filter devices. The invention is not confined to avionics units but could be used with other electronics units.

What I claim is:

1. An electronics unit comprising: an outer housing; electronics components within said housing and an electrical connector on a face of said housing making electrical connection with said components within said housing, wherein said unit includes a plurality of electrical devices connected between said connector and said housing, and wherein said devices are located on said face to one side of said connector and are accessible without removal of said connector.

2. An electronics unit according to claim 1, wherein said devices are transient voltage suppressors.

3. An electronics unit according to claim 1, wherein said devices each include a diode.

4. An electronics unit according to claim 1 and including a metal plate with a plurality of holes therein, wherein said devices are each located in respective ones of said holes in said plate.

5. An electronics unit according to claim 1 and including a removable panel, wherein said devices are located on said face beneath said panel.

6. An electronics unit according to claim 1, wherein each said device includes a clip by which electrical connection is made to said device.

7. An electronics unit according to claim 1 and including a support plate, wherein said devices and said connector are mounted on said support plate to be accessible on a front surface of said plate, and wherein said devices and contacts of said connector extend through said plate and are exposed on a rear surface of said support plate.

8. An electronics unit according to claim 7, including one or more circuit boards, wherein said circuit boards have contacts located on a forward surface arranged to make electrical contact with respective ones of said devices and said contacts exposed on said rear surface of said support plate.

9. An electronics unit according to claim 8, wherein said circuit boards are arranged electrically to interconnect said devices with said contacts of said connectors.

10. An electronics unit according to claim 1 including a filter module, said filter module including a plate, and wherein said plate supports an array of filters arranged in a configuration the same as contacts of said connector.

11. An electronics unit according to claim 10, wherein said filters each have a contact on a front surface of said filter plate and a contact on a rear surface of said filter plate.

12. An electronics unit according to claim 1 including a rear connector assembly, said rear connector assembly including a rear support plate, said rear support plate having one or more connectors mounted on a rear surface, one or more socket array boards mounted on a forward surface of said plate and one or more flexi-rigid circuits extending around one or more edges of said rear support plate to interconnect said connectors on said rear surface with said socket array boards on said forward surface.

13. An electronics unit according to claim 12 and including a plurality of filters, wherein said socket array boards are arranged to make electrical connection with said filters.

14. An electronics unit comprising: a first plate member, said first plate member supporting an electrical connector and a plurality of transient suppressor devices, said connector and said devices being exposed on an outer surface of said plate; a panel member removably secured with said first plate on an outer surface of said first plate and covering said transient suppressor devices; a second plate member secured with a rear surface of said first plate member, said second plate member supporting a plurality of filters disposed to connect with respective contacts in said electrical connector, said filters extending through said second plate member; and a third plate member secured with a rear of said second plate member, said third plate member supporting a plurality of contacts on a forward surface engaging respective ones of said filters, an electrical connector on a rear surface of said third plate and interconnections between said contacts on said forward surface and said connector on said rear surface such that electrical connection with said electrical connector on said first plate can be established by connection with said electrical connection on said third plate.

15. An avionics unit comprising: an outer housing; electronics components within said housing; and an electrical connector on a face of said housing, said connector being electrically connected with said components within said housing, wherein said unit includes a plurality of transient suppressors connected with said connector, said suppressors being located on said face, and a cover removably secured with said face such as to cover said suppressors, such that said suppressors are accessible after removal of said cover.
